(19) United States
(12) Patent Application Publication
(10) Pub. No.: US 2012/0228628 A1
(43) Pub. Date: Sep. 13, 2012

(54) SEMICONDUCTOR DEVICE AND METHOD OF FABRICATING THE SAME

(75) Inventors: Hiroyuki Onoda, Wappingers Falls, NY (US); Hiroyuki Oota, Wappingers Falls, NY (US)

(73) Assignee: TOSHIBA AMERICA ELECTRONIC COMPONENTS, INC., Irvine, CA (US)

(21) Appl. No.: 13/041,732

(22) Filed: Mar. 7, 2011

(51) Int. Cl. H01L 29/12; H01L 21/336

(52) U.S. Cl. 257/77; 438/285; 438/197; 257/E29.068; 257/E21.409

(57) ABSTRACT

A semiconductor device and methods of fabricating semiconductor devices are provided. A method involves forming a semiconductor substrate on a source region and a drain region, the semiconductor substrate comprises a first crystal. The method also involves forming an epitaxial layer of a second crystal on the semiconductor substrate. The first crystal has a first lattice constant and the second crystal has a second lattice constant. The first epitaxial layer does not touch a spacer or a gate electrode. Forming the epitaxial layer can comprise forming a first epitaxial layer and a second epitaxial layer, wherein the first epitaxial layer has a conductivity type impurity that is less than the conductivity type impurity of the second epitaxial layer.

### FIELD

The following description relates generally to semiconductors and methods of using a late embedded silicon-germanium (e-SiGe) process to fabricate a semiconductor device.

### BACKGROUND

As transistor design is improved and evolved, the number of different types of transistors continues to increase. Multi-gate fin field effect transistors (e.g., FinFETs) are developed to provide scaled devices with faster drive currents and reduced short channel effects over planar FETs. Examples of multi-gate fin field effect transistors include double-gate FinFETs and tri-gate FinFETs. Double-gate FinFETs are FETs in which a channel region is formed in a thin semiconductor fin. The source and drain regions are formed in the opposing ends of the fin on either side of the channel region. Gates are formed on each side of the thin semiconductor fin, and in some cases, on the top or bottom of the fin as well, in an area corresponding to the channel region. Tri-gate FinFETs have a similar structure to that of double-gate FinFETs. The fin width and height of the tri-gate FinFETs, however, are approximately the same so that gates can be formed on three sides of the channel, including the top surface and the opposing sidewalls. The height to width ratio is generally in the range of 3:2 to 2:3 so that the channel will remain fully depleted and the three-dimensional field effects of a tri-gate FinFET will give greater drive current and improved short-channel characteristics over a planar transistor.

Late embedded silicon-germanium (SiGe) has been formed at a source region and/or drain region before extension and halo implant in an attempt enhance positive channel field effect transistor (PFET) performance and to reduce performance variables. A buffer layer e-SiGe process has been used in an attempt to obtain higher Ge concentration or to suppress B diffusion from B-doped e-SiGe layer. However, both the late eSiGe process and the buffer layer process are less than ideal because the buffer layer prevents a connection between an extension region and the B-doped SiGe layer. Thus, a high resistance region is induced between the extension region and the eSiGe B doped layer.

### BRIEF DESCRIPTION OF THE DRAWINGS

FIGS. 1A through 1C illustrate cross sectional views of methods for fabricating a semiconductor device utilizing a conventional late eSiGe process.

FIG. 2 illustrates a cross sectional view of portion of a semiconductor device that is formed utilizing a conventional buffer layer process.

FIG. 3 illustrates a portion of a semiconductor device showing a structure of the eSiGe buffer layer process.

FIG. 4 illustrates a cross sectional representation of a portion of a semiconductor device utilizing an improved eSiGe structure for Late-eSiGe, according to an aspect.

FIG. 5 illustrates a picture of a cross-section of a layer structure, according to an aspect.

FIG. 6 illustrates a method for forming a semiconductor, according to an aspect.

FIG. 7 illustrates a method for fabricating a semiconductor device, according to an aspect.

### DETAILED DESCRIPTION

The subject innovation provides a late embedded silicon-germanium (e-SiGe) process for forming a semiconductor device where an extension region and a halo region are formed before an epitaxial layer is formed. Further, the disclosed aspects provide for a space to be created, wherein the space is utilized to provide a connection between an extension region, implanted before eSiGe growth, and a B-doped SiGe layer. The space can be created by lowering a buffer layer at a sidewall region of the semiconductor device.

The disclosed aspects can enhance positive channel field effect transistor (PFET) performance. A late e-SiGe process comprises formed SiGe at a source region and/or drain region before extension and halo implant. The late e-SiGe process can enhance PFET performance and reduce variability. The performance enhancement is a result of there being no stress relaxation induced by halo implant. The mitigation of performance variability is a result of there being no extension implant after e-SiGe formation.

Further, a buffer layer e-SiGe process is utilized to obtain a higher germanium (Ge) concentration and/or to suppress B diffusion from B doped e-SiGe layer. The buffer layer is non-doped because higher B concentration can degrade short channel effect. If late e-SiGe process and buffer layer e-SiGe process are combined (or utilized at substantially the same time), additional implant after e-SiGe formation is needed to mitigate resistance because extension region and e-SiGe main B doped layer is not connected due to the non-doped buffer layer. This extra implant loses the late e-SiGe benefit, which is mitigation of variability.

The disclosed aspects overcome the aforementioned deficiencies of late e-SiGe and buffer layer e-SiGe processes. The disclosed aspects provide a space that provides a connection between the extension region implanted before eSiGe growth and B-doped SiGe layer by lowering buffer layer at the sidewall region.

An aspect relates to a semiconductor structure that comprises a semiconductor substrate and a multi-layer epitaxial layer formed on the semiconductor substrate. The semiconductor substrate comprises a first crystal having a first lattice constant. The multi-layer epitaxial layer comprises a second crystal having a second lattice constant. The first lattice constant is different from the second lattice constant. The multi-layer epitaxial layer comprises a first epitaxial layer and a second epitaxial layer. A first conductivity type impurity of the first epitaxial layer is less than a second conductivity type impurity of the second epitaxial layer.

In an aspect, the first epitaxial layer does not touch a spacer nor a gate electronode. In another aspect, the multi-layer epitaxial layer comprises a multi-layer laminated epitaxial layer. In a further aspect, the second epitaxial layer touches a Si channel.

The semiconductor structure can also comprise an extension region that is implanted before deposition of the multi-layer epitaxial layer. In an aspect, an extension region and a halo region are formed before the multi-layer epitaxial layer is formed.

In an aspect, at least one layer of the multi-layer epitaxial layer is formed of silicon-germanium (SiGe). In another aspect, at least one layer of the multi-layer epitaxial layer is formed of silicon carbide (SiC). According to some aspects, the first epitaxial layer comprises no conductivity type impurity.

A further aspect relates to a method for forming a semiconductor. The method comprises forming a semiconductor substrate on a source region and a drain region. The semiconductor substrate comprises a first crystal. The method also comprises forming an epitaxial layer of a second crystal on the semiconductor substrate. The first crystal has a first lattice constant and the second crystal has a second lattice constant.

In an aspect, forming the epitaxial layer comprises forming a laminated epitaxial layer. In another aspect, forming the epitaxial layer comprises forming a first epitaxial layer that does not touch a spacer or a gate electrode. In a further aspect, forming the epitaxial layer comprises forming a first epitaxial layer comprising no conductivity type impurity.

In some aspects, forming the epitaxial layer comprises forming a first epitaxial layer and a second epitaxial layer, wherein the first epitaxial layer has a conductivity type impurity that is less than the conductivity type impurity of the second epitaxial layer. In other aspects, forming the epitaxial layer comprises forming a first epitaxial layer and a second epitaxial layer, wherein the second epitaxial layer comprises a conductivity type impurity and is touched to a Si channel and an extension region is implanted before deposition of the epitaxial layer.

The method can also include forming an extension region and a halo region before forming the epitaxial layer. In an aspect, forming the epitaxial layer comprises forming the epitaxial layer with Silicon Germanium (SiGe). In another aspect, forming the epitaxial layer comprises forming the epitaxial layer with Silicon Carbide (SiC).

Another aspect relates to a method for fabricating a semiconductor device. The method comprises forming a semiconductor substrate on a source region and a drain region, the semiconductor substrate is formed of a first crystal. The method also comprises implanting an extension region and forming the extension region and a halo region. Further, the method includes forming a first epitaxial layer on the semiconductor substrate, the first epitaxial layer does not touch a spacer or a gate electronode. The method also includes forming a second epitaxial layer that touches a Si channel. The second epitaxial layer has a conductivity type impurity that is more than the conductivity type impurity of the first epitaxial layer, wherein at least one of the first epitaxial layer and the second epitaxial layer are formed of a second crystal having a lattice constant that is different from the lattice constant of the first crystal. In an aspect, the first epitaxial layer has a first lattice constant and the second epitaxial layer has a second lattice constant, wherein the first lattice constant is different from the second lattice constant.

The various aspects are now described with reference to the drawings. In the following description, for purposes of explanation, numerous specific details are set forth in order to provide a thorough understanding of the one or more aspects. It may be evident, however, that the various aspects may be practiced without these specific details. In other instances, well-known structures and devices are shown in block diagram form in order to facilitate describing the one or more aspects.

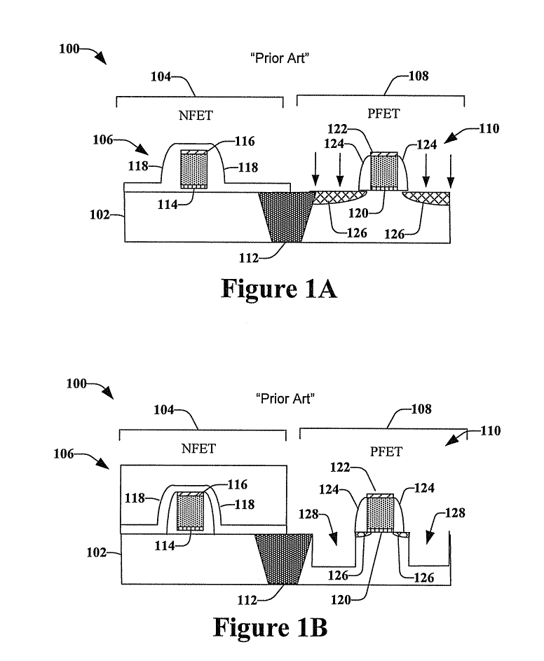

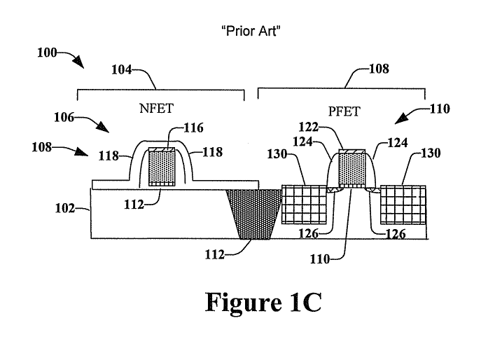

Turning now to the figures, FIGS. 1A through 1C illustrate cross sectional views of methods for fabricating a semiconductor device 100 utilizing a conventional late eSiGe process. As illustrated by FIG. 1A, on a semiconductor substrate 102, an n-type transistor region 104 for forming an n-type transistor 106 (e.g., negative channel field effect transistor (NFET)) is isolated from a p-type transistor region 108 for forming a p-type transistor 110 (e.g., positive channel field effect transistor (PFET)). The isolation is created by the formation of an element isolation region 112. In the n-type transistor region 104 are formed a gate insulating film 114, a gate electrode 116, and a sidewall 118. In the p-type transistor region 108 are formed a gate insulating film 120, a gate electrode 122, and a sidewall 124. As shown, there is extension/eSiGe spacer deposition 126. After depositing a material on the gate sidewalls, the material film is etched by a RIE (Reactive Ion Etching) method, which results in the gate sidewalls being formed. There is an extension/halo implant on the p-type transistor region 108.

As illustrated by FIG. 1B, a trench 128 or recess is formed by etching the p-type transistor region 108 of the semiconductor substrate 102 using the gate electrode 122 and the sidewall 124 as a mask. The etching is conducted so as not to reach the n-type transistor region 104. In further detail, for example, the etching is conducted after forming a resist using a lithography method in the n-type transistor region 104 of the semiconductor substrate 102.

As shown in FIG. 1C, a crystal, such as a SiGe crystal, for example, is epitaxially grown using the surface of the semiconductor substrate 102 exposed inside the trench 128 as a base, thereby forming the epitaxial crystal layer 130 in the p-type transistor region 108. There can also be a silicon nitride (SiN) RIB. Further, there can be a halo implant on the n-type transistor region 104.

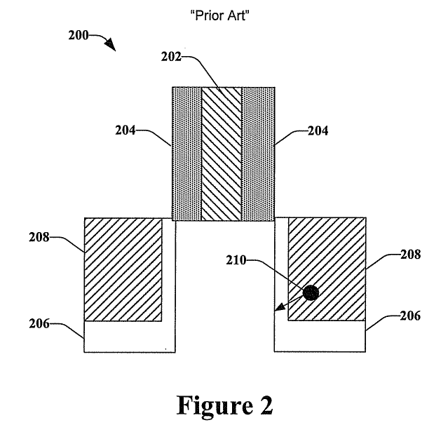

FIG. 2 illustrates a cross sectional view of portion of a semiconductor device that is formed utilizing a conventional buffer layer process. The illustrated portion of the semiconductor device represents a PFET 200, according to an aspect. The PFET 200 comprises a gate electrode 202 formed on a semiconductor substrate and sidewalls 204. Also illustrated are a buffer layer 206 and an epitaxial crystal layer 208.

There can be a high B concentration eSiGe and High Ge concentration within the epitaxial crystal layer 208. Further, the eSiGe buffer layer 206 suppress to diffuse B atoms 210, which can have a good Vth roll-off. The eSiGe buffer layer 206 (non B doped) can have a low Ge concentration. The buffer layer 206 has a low Ge concentration, which helps to mitigate SiGe dislocation caused by high Ge concentration.

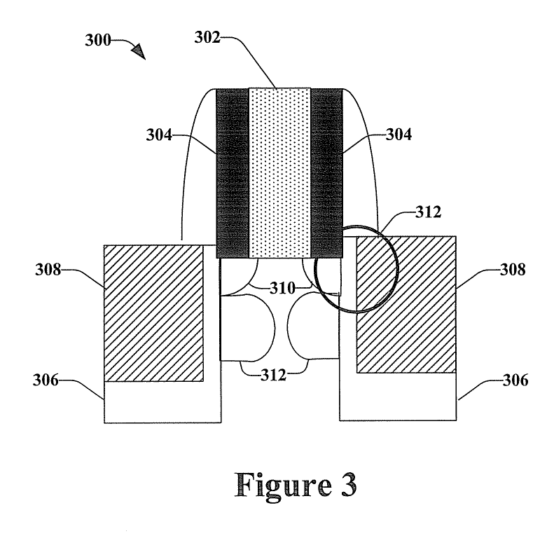

The conventional processes shown in FIGS. 1A-1C and 2 can prevent a connection between the extension region, which is implanted before eSiGe growth, and the B-doped SiGe layer. This can induce a high resistance region between the extension region and the eSiGe B doped layer, as shown in FIG. 3. Thus, additional implant is needed after eSiGe growth in order to reduce the resistance. However, the additional implant can degrade Vth variability because the implant depth is affected by eSiGe fill height.

FIG. 3 illustrates a portion of a semiconductor device showing a structure of the eSiGe buffer layer process. The illustrated portion of the semiconductor device is a PFET 300, for example. The PFET 300 comprises a gate electrode 302 formed on a semiconductor substrate and sidewalls 304. Also illustrated are a buffer layer 306 and an epitaxial crystal layer 308. The buffer layer 306 can be an eSiGe buffer layer (non B doped) with low Ge concentration. An extension region 310 and a halo region 312 are formed, as described above.

As illustrated within the circle 312, a high resistance region is formed. Thus, the late eSiGe in combination with a buffer layer process can produce the need for additional implant after eSiGe growth in order to reduce resistance. However, implant degrades Vth variability. The disclosed aspects can overcome the issues produced when late eSiGe is utilized at substantially the same time as a buffer layer process.

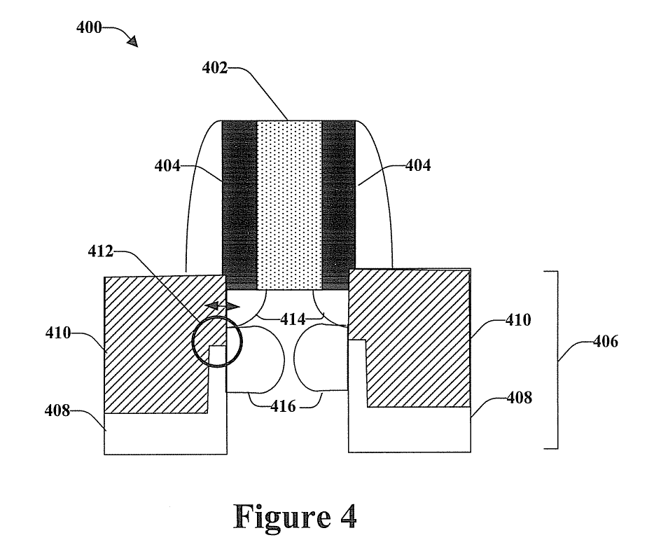

FIG. 4 illustrates a cross sectional representation of a portion of a semiconductor device utilizing an improved eSiGe structure for Late-eSiGe, according to an aspect. The portion of the semiconductor device can be a PFET portion 400. The PFET portion 400 comprises a gate electrode 402 formed on a semiconductor substrate and sidewalls 404.

Also illustrated is a multi-layer epitaxial layer 406. The multi-layer epitaxial layer 406 comprises a first epitaxial layer 408 and a second epitaxial layer 410. The first epitaxial layer 408 can be a buffer layer and the second epitaxial layer 410 can be an epitaxial crystal layer, according to an aspect.

The first epitaxial layer 408 (or buffer layer) is lowered, as illustrated by the circle 412. The lowered buffer layer allows for space in order to form a connection between an extension region and eSiGe B doped layer. The buffer layer does not need to be adjacent to the channel region and extension region in terms of B diffuse suppression and eSiGe growth.

According to some aspects, the first epitaxial layer 408 can be formed so that the first epitaxial layer 408 does not touch a spacer nor a gate electronode. In accordance with some aspects, a first conductivity type impurity of the first epitaxial layer 408 is less than a second conductivity type impurity of the second epitaxial layer 410. In some aspects, the first epitaxial layer 408 comprises no conductivity type impurity.

According to some aspects, the semiconductor substrate can be formed on a source region and a drain region. The semiconductor substrate can be formed of a first crystal that has a first lattice constant. The multi-layer epitaxial layer 406 can be formed of a second crystal that has a second lattice constant. In accordance with some aspects, the first lattice constant is different from the second lattice constant.

The multi-layer epitaxial layer 406 can comprise a laminated epitaxial layer, according to some aspects. The second epitaxial layer 410 can touch a Si channel. An extension region 414 can be implanted before epitaxial layer deposition. According to some aspects, an extension region 414 and a halo region 416 are formed before the multi-layer epitaxial layer 406 is formed. In accordance with some aspects, the multi-layer epitaxial layer 406 is formed of SiGe. According to some aspects, the epitaxial layer is formed of Silicon Carbide (SiC).

A semiconductor device of the disclosed aspects can comprise a multi-layer structure over a semiconductor substrate. According to an aspect, the semiconductor substrate is a bulk-Si substrate. One or more of the layers of the multi-layer structure can be formed by chemical vapor deposition (CVD) such as plasma enhanced chemical vapor deposition (PECVD), low-pressure chemical vapor deposition (LPCVD), high-pressure chemical vapor deposition (HPCVD), or the like.

The multi-layer structure can contain N layers, where N is an integer, which can be two or more. In one embodiment, the multi-layer structure contains a first layer or a lowermost layer over the semiconductor substrate, a second layer or an intermediate layer over the first layer, and a third layer or an uppermost layer over the second layer.

One or more of the layers of the multi-layer structure can contain dielectric materials including oxides such as silicon oxide; nitrides such as silicon nitride, silicon rich nitride, and oxygen rich silicon nitride; and the like. According to an embodiment, the first layer contains silicon-geranium (SiGe). According to some embodiments, the second layer contains silicon. For example, a SiGe layer can be grown on a silicon substrate and a silicon layer can be grown on the SiGe layer. The SiGe layer will turn into an insulator film later in the process during oxidization.

The thicknesses of the layers of the multi-layer structure may vary and the layers independently have any suitable thickness that depends on the desired implementations of the semiconductor device being fabricated. In one embodiment, the thickness of the second layer is about 10 nm or more and about 100 nm or less. In another embodiment, the thickness of the second layer is about 15 nm or more and about 80 nm or less. In yet another embodiment, the thickness of the second layer is about 20 nm or more and about 60 nm or less. In still yet another embodiment, the thickness of the second layer is about 30 nm.

In one embodiment, a thickness of the third layer is about 5 nm or more and about 100 nm or less. In another embodiment, the thickness of the third layer is about 7 nm or more and about 60 nm or less. In yet another embodiment, the thickness of the third layer is about 10 nm or more and about 40 nm or less. In still yet another embodiment, the thickness of the third layer is about 14 nm.

An Nth layer or an uppermost layer of the multi-layer structure can be a cap layer. The Nth layer can serve as a chemical-mechanical polishing (CMP) stop layer in a subsequent process. The Nth layer can contain dielectric materials including oxides such as silicon oxide; nitrides such as silicon nitride, silicon rich nitride, and oxygen rich silicon nitride; and the like. The Nth layer can be formed by CVD such as PECVD, LPCVD, HPCVD, or the like.

The portions of the semiconductor substrate and the multi-layer structure can be removed by any suitable technique, for example, etching. Portions of the semiconductor substrate and the multi-layer structure can be removed by contacting the semiconductor substrate and the multi-layer structure with any suitable etchant that does not substantially damage and/or remove other components of the semiconductor device. Choice of a suitable process and reagents of etching depends on, for example, the materials of the semiconductor substrate and the multi-layer structure, the width and height of the fins, the desired implementations of the semiconductor device being fabricated, and the like.

The multi-layer structure can have one or more intermediate layers between the first layer (or a lowermost layer) and the Nth layer (or an uppermost layer). At least one intermediate layer can have a substantially uniform thickness across the semiconductor substrate. The intermediate layer can be formed by CVD such as PECVD, LPCVD, HPCVD, or the like.

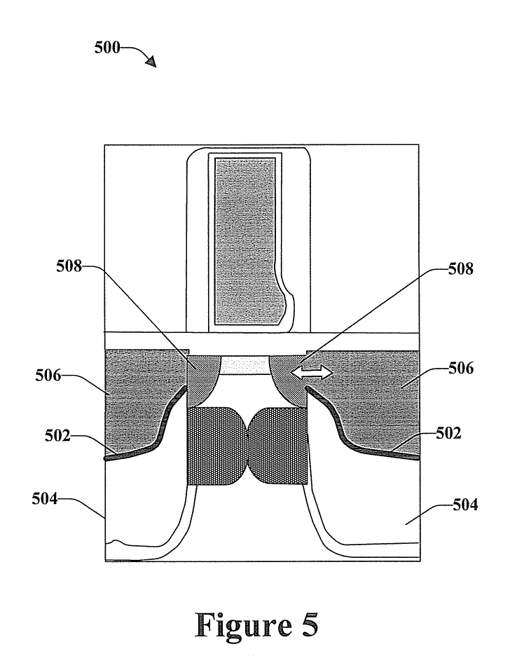

FIG. 5 illustrates a picture of a cross-section of a layer structure 500, according to an aspect. The resistance can be reduced dramatically (as compared to conventional processes) by connecting between an extension region and an eSiGe B doped layer. The process of the disclosed aspects does not require additional implant, thus, the variability can be very small. The line 502 indicates the boundary between the first layer 504 and the second layer 506. The second layer 506 is connecting the extension region 508.

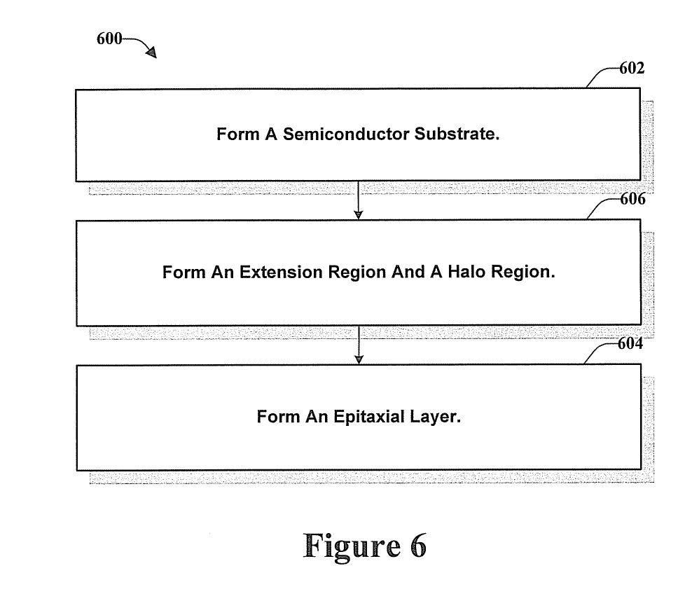

FIG. 6 illustrates a method 600 for forming a semiconductor according to an aspect. The method 600 starts, at 602, when a semiconductor substrate is formed on a source region and a drain region. The semiconductor substrate comprises a first crystal. At 604, an epitaxial layer is formed. The epitaxial layer can be a multi-layer epitaxial layer. The epitaxial layer is formed of a second crystal. The first crystal of the semiconductor substrate has a first lattice constant and the second crystal of the epitaxial layer has a second lattice constant. According to some aspects, the first lattice constant is different from the second lattice constant. Additionally, method 600 can also include fowling, at 606, an extension region and a halo region before the forming the epitaxial layer (at 604).

In an aspect, forming the epitaxial layer comprises forming the epitaxial layer with SiGe. In another aspect, forming the epitaxial layer comprises forming the epitaxial layer with SiC. For example, a first layer can be formed with SiGe and a second layer can be formed with SiC. In another example, a first layer can be formed with SiC and a second layer can be formed with SiGe. However, other combinations are also possible, according to some aspects.

Forming the epitaxial layer, at 604, can include forming a laminated epitaxial layer. The laminated epitaxial layer can be a multi-layer laminated epitaxial layer, according to an aspect.

In accordance with some aspects, forming the epitaxial layer, at 604, includes forming a first epitaxial layer that does not touch a spacer or a gate electrode. In another aspect, the first epitaxial layer comprises no conductivity type impurity.

According to some aspects, forming the epitaxial layer, at 604, comprises forming a first epitaxial layer and a second epitaxial layer. The first epitaxial layer has a conductivity type impurity that is less than the conductivity type impurity of the second epitaxial layer. In some aspects, forming the epitaxial layer, at 604, comprises forming a first epitaxial layer and a second epitaxial layer, wherein the second epitaxial layer comprises a conductivity type impurity and is touched to a Si channel and an extension region is implanted before deposition of the epitaxial layer.

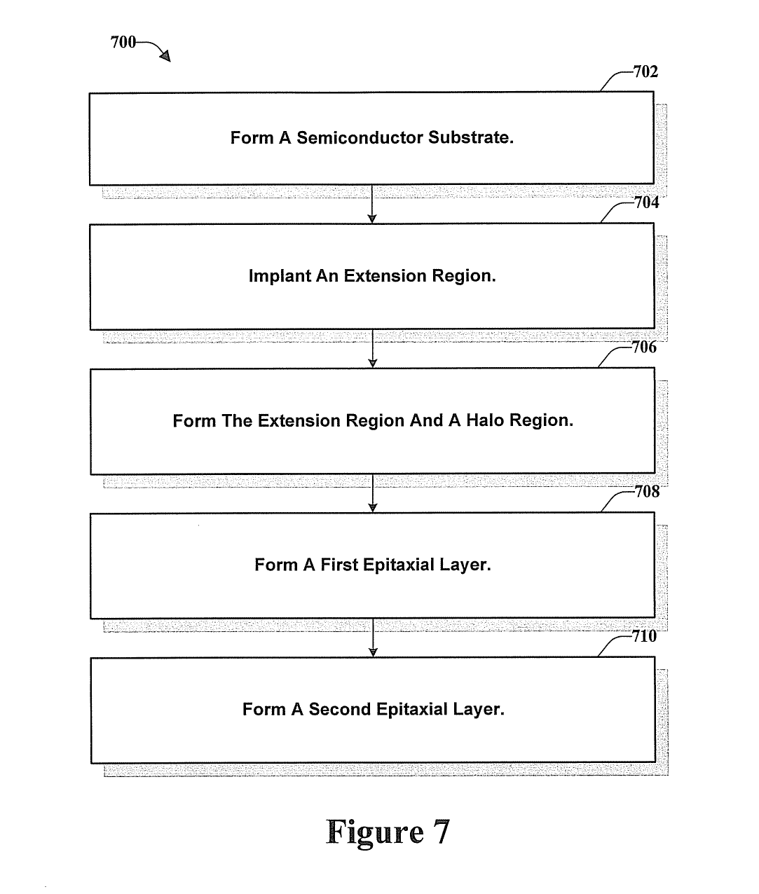

FIG. 7 illustrates a method 700 for fabricating a semiconductor device, according to an aspect. Method 700 starts, at 702, when a semiconductor substrate is formed on a source region and a drain region. The semiconductor substrate can be formed of a first crystal. At 704, an extension region is implanted and, at 706, the extension region and a halo region are formed.

A first epitaxial layer that does not touch a spacer or a gate electronode is formed, at 708. A second epitaxial layer that touches a Si channel is formed, at 710. The second epitaxial layer can have a conductivity type impurity that is more than the conductivity type impurity of the first epitaxial layer. At least one of the first epitaxial layer and the second epitaxial layer are formed of a second crystal having a lattice constant that is different from the lattice constant of the first crystal of the semiconductor substrate.

In accordance with some aspects, the first epitaxial layer has a first lattice constant and the second epitaxial layer has a second lattice constant, wherein the first lattice constant is different from the second lattice constant.

The various aspects disclosed herein provide a late epitaxially grown silicon-germanium process, which forms SiGe at a source region and/or a drain region before extension and halo implant. A space is created by lowering a buffer layer at a sidewall region. The space is utilized to connect an extension region and a B-doped SiGe layer.

With respect to any figure or numerical range for a given characteristic, a figure or a parameter from one range may be combined with another figure or a parameter from a different range for the same characteristic to generate a numerical range.

Other than in the operating examples, or where otherwise indicated, all numbers, values and/or expressions referring to quantities of ingredients, reaction conditions, etc., used in the specification and claims are to be understood as modified in all instances by the term “about.”

While, for purposes of simplicity of explanation, methods are shown and described as a series of blocks, it is to be understood and appreciated that the disclosed aspects are not limited by the number or order of blocks, as some blocks may occur in different orders and/or at substantially the same time with other blocks from what is depicted and described herein. Moreover, not all illustrated blocks may be required to implement methods described herein.

What has been described above includes examples of the disclosed innovation. It is, of course, not possible to describe every conceivable combination of components or methodologies for purposes of describing the disclosed innovation, but one of ordinary skill in the art can recognize that many further combinations and permutations of the disclosed innovation are possible. Accordingly, the disclosed innovation is intended to embrace all such alterations, modifications and variations that fall within the spirit and scope of the appended claims. Furthermore, to the extent that the term “contain,” “includes,” “has,” “involve,” or variants thereof is used in either the detailed description or the claims, such term can be inclusive in a manner similar to the term “comprising” as “comprising” is interpreted when employed as a transitional word in a claim.

1. A semiconductor structure, comprising:
a semiconductor substrate comprising a first crystal comprising a first lattice constant;
a multi-layer epitaxial layer formed on the semiconductor substrate, the multi-layer epitaxial layer comprising a second crystal comprising a second lattice constant, wherein the first lattice constant is different from the second lattice constant;
an extension region formed on the semiconductor substrate;
wherein the multi-layer epitaxial layer comprises:
a first epitaxial layer comprising a concave portion and failing to touch the extension region; and
a second epitaxial layer provided on the first epitaxial layer, the second epitaxial layer being thicker than the first epitaxial layer and filling the concave portion of the first epitaxial layer, wherein a first conductivity type impurity of the first epitaxial layer is less than a second conductivity type impurity of the second epitaxial layer.

2. The semiconductor structure of claim 1, wherein the first epitaxial layer does not touch a spacer nor a gate electronode.

3. The semiconductor structure of claim 1, wherein the multi-layer epitaxial layer comprises a multi-layer laminated epitaxial layer.

4. The semiconductor structure of claim 1, wherein the second epitaxial layer touches a Si channel.

5. The semiconductor structure of claim 1, wherein the extension region is implanted before deposition of the multi-layer epitaxial layer.

6. The semiconductor structure of claim 5, further comprising a halo region formed before the multi-layer epitaxial layer is formed.

7. The semiconductor structure of claim 1, wherein at least one layer of the multi-layer epitaxial layer is formed of silicon-germanium (SiGe).

8. The semiconductor structure of claim 1, wherein at least one layer of the multi-layer epitaxial layer is formed of silicon carbide (SIC).

9. The semiconductor structure of claim 1, wherein the first epitaxial layer comprises no conductivity type impurity.

10-20. (canceled)

21. The semiconductor structure of claim 1, further comprising a gate on the semiconductor substrate, wherein the gate comprises a gate electrode and the extension region is formed below the gate electrode and the extension region is provided in a lateral direction relative to the gate electrode, and wherein the second epitaxial layer is provided outside the extension region in the lateral direction and the second epitaxial layer touches the extension region in the lateral direction.

22. The semiconductor structure of claim 21, wherein the gate further comprises a gate insulating film provided under the gate electrode.
